(19) United States
(12) Patent Application Publication
(10) Pub. No.: US 2026/0303049 A1
(43) Pub. Date: Oct. 1, 2026

(54) INTEGRATED COMMON-MODE FILTER CORE FOR OPEN-ENDED WINDING ELECTRIC MOTOR

(71) Applicant: PURDUE RESEARCH FOUNDATION, West Lafayette, IN (US)

(72) Inventors: Woongkul LEE, West Lafayette, IN (US); Junhyuk IM, West Lafayette, IN (US)

(21) Appl. No.: 19/631,235

(22) Filed: Mar. 27, 2026

Related U.S. Application Data
(60) Provisional application No. 63/779,745, filed on Mar. 28, 2025.

(51) Int. Cl. H03H 7/01; H02K 1/14; H02K 3/18

(52) U.S. Cl. CPC H03H 7/01; H02K 1/14; H02K 3/18

(57) ABSTRACT

Technologies for an integrated common-mode filter include an electric machine having a stator core coupled to multiple stator windings in an open-end winding configuration. The stator windings extend through one or more common-mode filter cores. The stator core extends between two ends, and a common-mode filter core may be coupled to one or both ends of the stator core, or a common-mode filter core may be coupled between stator cores. The common-mode filter core may be formed from a soft magnetic material. The common mode filter core includes multiple arcuate inner core segments surrounding a central opening, multiple arcuate outer core segments surrounding the inner core segments, and multiple radial arms connecting the inner core segments and the outer core segments. Slots are defined between the radial arms, and the slots receive stator windings. Other embodiments are described and claimed.

### CROSS-REFERENCE TO RELATED APPLICATIONS

This application claims the benefit of and priority to U.S. Patent Application No. 63/779,745, entitled “INTEGRATED COMMON-MODE FILTER CORE FOR OPEN-ENDED WINDING ELECTRIC MOTOR,” which was filed on Mar. 28, 2025, and which is incorporated herein by reference in its entirety.

### BACKGROUND

Open-end winding (OEW) for electric motors is a promising solution for higher efficiency and reliability. OEW motors are already being used in many current electric vehicles (EVs). Such OEW motors typically exhibit large zero-sequence current (third-harmonic) due to the lack of a wye-connection between windings of the OEW motor. This zero-sequence current does not produce torque. Accordingly, output torque for typical OEW motors may be limited to about 85% of the maximum capability. Adding a common-mode (CM) filter between the inverter(s) and the electric machine may reduce zero-sequence current. However, traditional designs of CM filters are large and may require special windings, and are thus not suitable for modern motor drive, which has a highly integrated design.

### SUMMARY

According to one aspect of the disclosure, a device includes an electric machine and a common-mode filter core. The electric machine includes a stator core coupled to a plurality of stator windings. The stator core includes an elongated body extending from a first end to a second end, and the stator windings have an open-end winding configuration. The common-mode filter core is coupled to the first end of the stator core. The plurality of stator windings extend through the common-mode filter core.

In an embodiment, the device further includes a second common-mode filter core coupled to the second end of the stator core. The plurality of stator windings extend through the second common-mode filter core.

In an embodiment, the electric machine further includes a second stator core coupled to the plurality of stator windings. The common-mode filter core is coupled between the stator core and the second stator core.

In an embodiment, the common-mode filter core includes an arcuate inner core segment, an arcuate outer core segment, and a pair of radial arms that extend between the inner core segment and the outer core segment. A slot is defined between each radial arm of the pair of radial arms. A stator winding of the plurality of stator windings is received in the slot.

In an embodiment, the common-mode filter core includes a plurality of arcuate inner core segments distributed circumferentially around a central opening of the common-mode filter core, a plurality of arcuate outer core segments distributed circumferentially around the plurality of inner core segments, and a plurality of pairs of radial arms. Each pair of radial arms extends between an inner core segment of the plurality of inner core segments and an outer core segment of the plurality of outer core segments. A slot is defined between each arm of each pair of radial arms and between each pair of radial arms. A stator winding of the plurality of stator windings is received in each slot.

In an embodiment, the plurality of arcuate inner core segments includes a first inner core segment, the plurality of arcuate outer core segments includes a first outer core segment and a second outer core segment, and the plurality of pairs of radial arms includes a first pair of radial arms and a second pair of radial arms. The first pair of radial arms couples the first inner core segment and the first outer core segment, and the second pair of radial arms couples the first inner core segment and the second outer core segment. In an embodiment, a first slot is defined between the radial arms of the first pair of radial arms, a second slot is defined between the first pair of radial arms and the second pair of radial arms, and a third slot is defined between the radial arms of the second pair of radial arms. The first outer core segment and the second outer core segment are separated by the third slot. In an embodiment, the first slot and the second slot receive stator windings of a first phase and wherein the third slot receives stator windings of a second phase.

In an embodiment, the plurality of arcuate inner core segments further includes a second inner core segment, the plurality of arcuate outer core segments further includes a third outer core segment, and the plurality of pairs of radial arms further includes a third pair of radial arms and a fourth pair of radial arms. The third pair of radial arms couples the second inner core segment and the second outer core segment, and the fourth pair of radial arms couples the second inner core segment and the third outer core segment. In an embodiment, a first slot is defined between the second pair of radial arms and the third pair of radial arms. The first inner core segment and the second inner core segment are separated by the first slot.

In an embodiment, the plurality of arcuate inner core segments includes six inner core segments, the plurality of arcuate outer core segments includes six outer core segments, and the plurality of pairs of radial arms includes twelve pairs of radial arms. In an embodiment, twenty-four slots are defined between the pairs of radial arms and between each radial arm of each pair of radial arms.

In an embodiment, the plurality of arcuate inner core segments includes twelve inner core segments, the plurality of arcuate outer core segments includes twelve outer core segments; and the plurality of pairs of radial arms includes twenty-four pairs of radial arms. In an embodiment, forty-eight slots are defined between the pairs of radial arms and between each radial arm of each pair of radial arms.

In an embodiment, the common-mode filter core includes a plurality of arcuate inner core segments distributed circumferentially around a central opening of the common-mode filter core, a plurality of arcuate outer core segments distributed circumferentially around the plurality of inner core segment, and a plurality of radial arms. Each radial arm extends between an inner core segment of the plurality of inner core segments and an outer core segment of the plurality of outer core segments. A slot is defined between each of the plurality of radial arms, and wherein a stator winding of the plurality of stator windings is received in each slot. In an embodiment, the plurality of arcuate inner core segments includes six inner core segments, the plurality of arcuate outer core segments includes six outer core segments, and the plurality of radial arms comprises twelve radial arms. Twelve slots are defined between the plurality of radial arms.

In an embodiment, the common-mode filter core comprises a soft magnetic material.

According to another aspect, a device includes a common-mode filter core comprising a soft magnetic material. The common-mode filter core includes a plurality of arcuate inner core segments distributed circumferentially around a central opening of the common-mode filter core, a plurality of arcuate outer core segments distributed circumferentially around the plurality of inner core segments, and a plurality of radial arms. Each radial arm extends between an inner core segment of the plurality of inner core segments and an outer core segment of the plurality of outer core segments. A slot is defined between each of the plurality of radial arms, and wherein each slot is configured to receive a stator winding of an electric machine.

In an embodiment, the plurality of arcuate inner core segments includes six inner core segments, the plurality of arcuate outer core segments includes six outer core segments, and the plurality of radial arms comprises twenty-four radial arms. Twenty-four slots are defined between the radial arms.

In an embodiment, the plurality of arcuate inner core segments includes twelve inner core segments, the plurality of arcuate outer core segments includes twelve outer core segments, and the plurality of radial arms includes forty-eight radial arms. Forty-eight slots are defined between the radial arms.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified block diagram of at least one embodiment of a system with an integrated common-mode filter core for an open-end winding electric motor;

FIG. 2 is a perspective view of at least one embodiment of an open-end winding electric motor with a single-ended integrated common-mode filter core according to the system of FIG. 1;

FIG. 3 is a perspective view of at least one embodiment of an open-end winding electric motor with a dal-ended integrated common-mode filter core according to the system of FIG. 1;

FIG. 4 is a schematic cross-sectional view of at least one embodiment of an integrated common-mode filter core of FIGS. 1-3;

FIG. 5 is a schematic diagram illustrating an equivalent circuit of the system of FIGS. 1-4;

FIG. 6 is a chart illustrating simulated experimental results that may be achieved by the integrated common-mode filter core of FIG. 4;

FIG. 7 is a perspective view of at least one embodiment of a four-pole, twelve slot open-ended winding electric motor with an integrated common-mode filter core according to the system of FIG. 1;

FIG. 8 is a schematic top view of at least one embodiment of the integrated common-mode filter core of FIG. 7; and

FIG. 9 is a schematic diagram illustrating at least one embodiment of an open-end winding electric motor with inverters.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

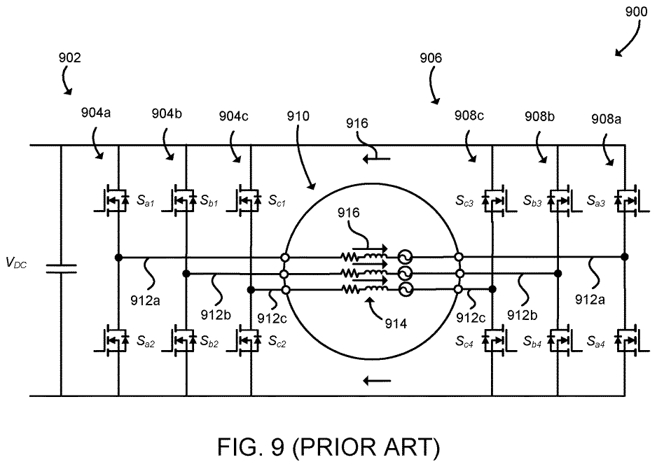

Open-end winding (OEW) electric motors may provide higher efficiency and reliability as compared to other electric motor configurations. Referring now to FIG. 9, a simplified schematic diagram 900 shows a typical OEW machine. The illustrative OEW system includes an inverter 902 having three legs 904a, 904b, 904c, and a second inverter 906 having three legs 908a, 908b, 908c. A motor 910 includes three phase wires 912a, 912b, 912c. Each of the phase wires 912a, 912b, 912c is coupled to the open ends of a corresponding stator winding 914 (e.g., the phase wires 912a, 912b, 912c are coupled to respective stator windings 914a, 914b, 914c). The motor 910 does not include a delta or wye connection that connects the stator windings 914 together. As shown, each phase wire 912 is coupled to a respective leg 904, 908 of the inverters 902, 906. That is, the phase wire 912a is coupled to the leg 904a of the inverter 902 and the leg 908a of the inverter 906; the phase wire 912b is coupled to the leg 904b of the inverter 902 and the leg 908b of the inverter 906; and the phase wire 912c is coupled to the leg 904c of the inverter 902 and the leg 908c of the inverter 906. As shown, zero-sequence current 916 can circulate through the stator windings 914. This zero-sequence current 916 does not generate torque.

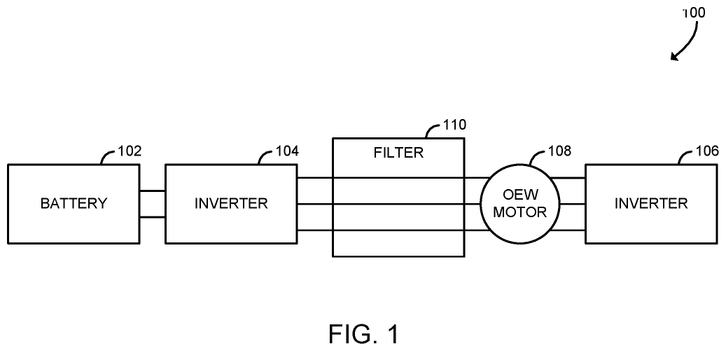

Referring now to FIG. 1, one potential embodiment of a system 100 with an integrated common-mode filter core for an open-end winding electric motor includes a battery 102 or other power supply, a pair of inverters 104, 106, an open-end winding (OEW) motor 108, and an integrated common-mode filter or choke 110. As shown, the inverters 104, 106 are connected to three phase wires, which are connected to the OEW motor 108 in an open-end winding configuration, similar to the configuration described above. The filter 110 is magnetically coupled to the windings of the OEW motor 108, and as described further below is physically integrated with the OEW motor 108.

As described further below, the common-mode filter core 110 may be coupled directly to the phase wire (i.e., stator windings) of the OEW motor 108. The CM filter 110 or choke reduces zero-sequence current, which may achieve further improvement of the OEW motor 108. For example, by reducing zero-sequence current, output torque of the OEW motor 108 may be increased closer to maximum capability of the OEW machine, for example by 15%. Additionally, the illustrative CM filter 110 reduces zero-sequence current without requiring complicated modulation techniques, which may reduce controller/inverter complexity or cost as compared to existing modulation techniques. Further, the illustrated CM filter 110 is highly integrated with the OEW motor 108 and thus reduces size, reduces cable costs, improves ease of manufacturing, and is otherwise suitable for packaging in a modern EV or other high-performance application. For example, as described further below, the CM filter 110 may share the main motor stator winding (thus eliminating additional windings and/or bypass connections) and may be physically integrated with the stator core, saving space.

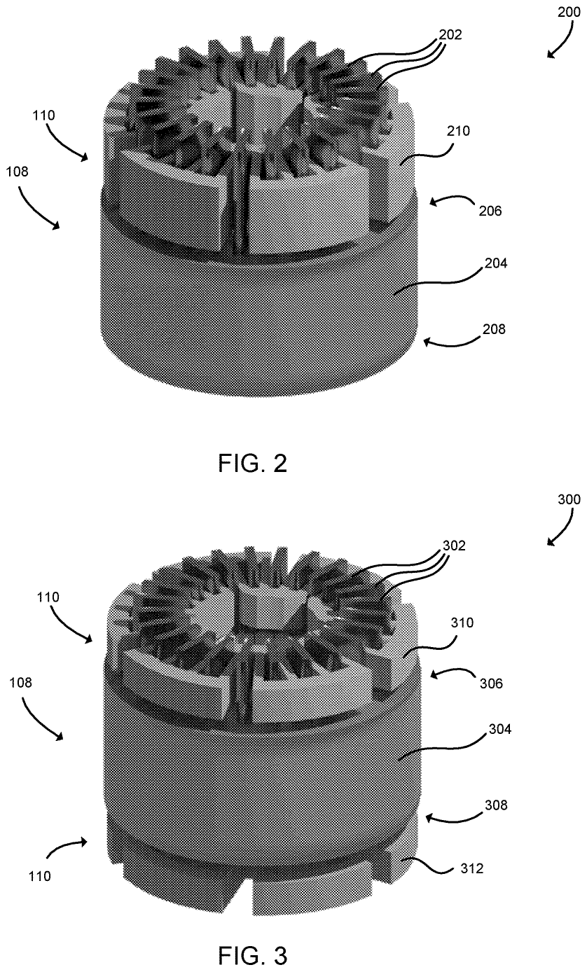

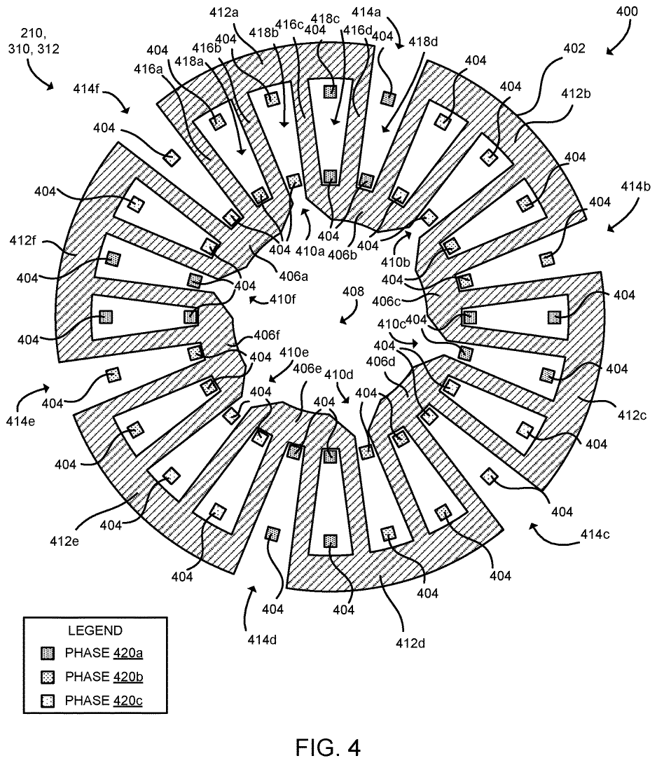

Referring now to FIG. 2, an integrated motor-filter system 200 is shown in a perspective view. The illustrative system 200 includes multiple stator windings 202, which are arranged radially around an opening which receives a rotor (not shown). The stator windings 202 are shown in simplified form in FIG. 2. The stator windings 202 may be distributed windings (e.g., for EV traction motor applications) or concentrated windings (e.g., for drone or robotics applications). The system further includes a stator core 204, which extends from one end 206 to another end 208. Multiple slots are defined through the stator core 204, each of which receives a stator winding 202 of the stator windings 202. The system 200 further includes an integrated common-mode filter core 210 positioned next to the end 206 of the stator core 204. Similar to the stator core 204, multiple slots are defined through the filter core 210, and each of those slots also receives a stator winding 202. Thus, the illustrative system 200 operates as an integrated OEW motor 108 with filter 110 as shown in FIG. 1. One potential embodiment of the filter core 210 is shown in FIG. 4 and described further below.

Referring now to FIG. 3, another integrated motor-filter system 300 is shown in a perspective view. Similar to the system 200 of FIG. 2, the illustrative system 300 includes multiple stator windings 302, which are arranged radially around an opening which receives a rotor (not shown). Similar to the system 200, the windings 302 may be distributed windings or concentrated windings. The system further includes a stator core 304, which extends from one end 306 to another end 308. Multiple slots are defined through the stator core 304, each of which receives a stator winding 302 of the stator windings 302. The system 300 further includes an integrated common-mode filter core 310 positioned next to the end 306 of the stator core 304, and another integrated common mode filter core 312 positioned next to the end 308 of the stator core 304. Similar to the stator core 304, multiple slots are defined through each of the filter cores 310, 312, and each of those slots also receives a stator winding 302. Thus, the illustrative system 300 operates as an integrated OEW motor 108 with filter 110 as shown in FIG. 1. One potential embodiment of the filter cores 310, 312 is shown in FIG. 4 and described further below.

FIGS. 2 and 3 illustrate the OEW motor 108 as 4-pole, 24-slot permanent magnet synchronous motor (PMSM). However, it should be understood that in other embodiments, the OEW motor 108 may have a different number and/or arrangement of poles and/or slots, and/or may be a different type of motor or other electric machine. For example, in an embodiment, the OEW motor may be an 8-pole, 48-slot OEW motor suitable for an electric vehicle traction motor. As another example, in an embodiment, the OEW motor may be a 42-pole, 36-slot motor suitable for robotics applications. In such embodiments, the integrated filter core may provide high-frequency EMI reduction. Similarly, other embodiments may have different numbers and/or arrangements of filter core(s) and/or stator core(s). For example, in embodiment, a system may include two stator cores with a single integrated filter core positioned between the stator cores.

Referring now to FIG. 4, a schematic cross-sectional view of a system 400 including an integrated common-mode filter core 402 and multiple stator windings 404 is shown. The filter core 402 is one potential embodiment of any of the filter cores 210, 310, 312 shown in FIGS. 2-3 and described above. The filter core 402 is illustratively formed from a soft magnetic material such as silicon steel, and may be formed from laminated steel in some embodiments. In other embodiments, the filter core 402 may be formed from higher permeability material such as ferrite, nanocrystalline core material, or other material. In some embodiments, the filter core 402 may be embodied as another high-frequency magnetic material. Thickness of the filter core 402 may be optimized for particular applications. For example, increasing the thickness of the filter core 402 increases the damping of zero-series current, while requiring a larger mechanical volume for the filter core 402. Additionally or alternatively, in some embodiments, the filter core 402 may be formed from multiple layers of different materials. Each of those materials may have different properties suitable for filtering different frequencies (e.g., a low-frequency filter layer, a mid-frequency filter layer, and a high-frequency filter layer, or other configuration).

The filter core 402 includes multiple arcuate inner core segments 406 distributed circumferentially around a central opening 408. The opening 408 may be sized to receive a rotor, a shaft, or other component of a motor 108. The inner core segments 406 are separated from each other by respective inner core openings 410. As shown, the illustrative filter core 402 includes six arcuate inner core segments 406a, 406b, 406c, 406d, 406e, 406f, which are separated by six respective inner core openings 410a, 410b, 410c, 410d, 410e, 410f.

The filter core 402 further includes multiple arcuate outer core segments 412 distributed circumferentially around the inner core segments 406. The outer core segments are separated from each other by outer core openings 414. As shown, the illustrative filter core 402 includes six arcuate inner core segments 406a, 406b, 406c, 406d, 406e, 406f, which are separated by six respective inner core openings 410a, 410b, 410c, 410d, 410e, 410f.

The filter core 402 further includes multiple radial arms 416 that extend outwardly from the inner core segments 406 to the outer core segments 412. For example, as shown in FIG. 4, a pair of radial arms 416a, 416b connect the inner core segment 406a to the outer core segment 412a. Another pair of radial arms 416c, 416d connect the outer core segment 412a to the inner core segment 406b. Similar pairs of radial arms 416 connect the remaining inner core segments 406 and outer core segments 412. Those radial arms 416 are not labeled in FIG. 4 so as not to obscure the disclosure thereof. The illustrative filter core 402 includes twenty-four radial arms 416.

As shown, the illustrative filter core 402 includes the same number of inner core segments 406 as outer core segments 412. The outer core segments 412 are rotationally offset from the inner core segments 406 such that each inner core segment 406 is coupled to two adjacent outer core segments 412 (and vice versa). Illustratively, each inner core segment 406 is connected to adjacent outer core segments 412 by four radial arms 416, with one pair of radial arms 416 connected to each of the adjacent outer core segments 412. Similarly, each outer core segment 412 is connected to adjacent inner core segments 406 by four radial arms 416, with one pair of radial arms 414 connected to each of the adjacent inner core segments 406. In other words, an inner core segment 406 is connected by a pair of radial arms 416 to one of the outer core segments 412 and by another pair of radial arms 416 to an adjacent other one of the outer core segments 412.

A slot 418 is defined between each of the radial arms 416. For example, as shown in FIG. 4, a slot 418a is defined between the radial arms 416a, 416b; a slot 418b is defined between the radial arms 416b, 416c; a slot 418c is defined between the radial arms 416c, 416d; and a slot 418d is defined between the radial arm 416d and a radial arm that connects the inner core segment 406b and the outer core segment 412b. Each of the slots 418a, 418c is enclosed by the body of the filter core 402. The slot 418b is in communication with the inner slot opening 410a, and the slot 418d is in communication with the outer slot opening 414a. Similar slots 418 are defined by the radial arms 416 that connect the remaining inner core segments 406 and outer core segments 412. Accordingly, the inner core segments 406 are spaced apart from each other such that each inner core segment 406 is separated from each adjacent inner core segment 406 by a corresponding slot 418. Similarly, the outer core segments 412 are spaced apart from each other such that each outer core segment 412 is separated from each adjacent outer core segment 412 by a corresponding slot 418. As shown, the illustrative filter core 402 includes twenty-four slots 418. Of course, other arrangements of core segments 406, 412, radial arms 416, and/or slots 418 are possible for other configurations of motors.

Each slot 418 receives a stator winding 404. As shown by the legend of FIG. 4, the stator windings 404 are grouped into three phases 420a, 420b, 420c. Two stator windings 404 of each phase 420 are positioned in adjacent slots 418. Each pair of adjacent slots 418 in a particular phase 420 is positioned adjacent to pairs of slots 418 in the other two phases 420.

In operation, the filter core 402 operates as a common-mode filter or a common-mode choke. The filter core 402 reduces zero-sequence current (ZSC) and in some embodiments may reduce electromagnetic interference (EMI).

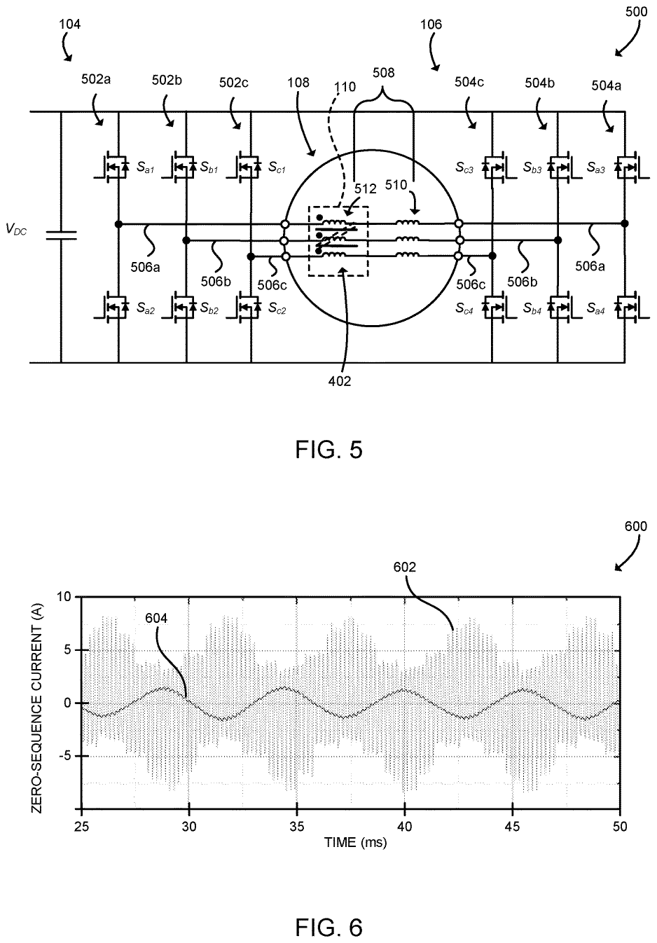

Referring now to FIG. 5, a simplified schematic diagram 500 shows an illustrative embodiment of an OEW motor 108 with integrated common mode filter 110 such as the filter core 402. As shown, the illustrative system includes an inverter 104 having three legs 502a, 502b, 502c, and a second inverter 106 having three legs 504a, 504b, 504c. A motor 108 includes three phase wires 506a, 506b, 506c. Each of the phase wires 506a, 506b, 506c is coupled to the open ends of a corresponding stator winding 508 (e.g., the phase wires 506a, 506b, 506c are coupled to respective stator windings 508a, 508b, 508c). The stator windings 508 are further divided into windings 510 positioned within the stator core of the motor 108 and head windings 512 positioned outside of the stator core. The motor 108 does not include a delta or wye connection that connects the stator windings 508 together. As shown, each phase wire 506 is coupled to a respective leg 502, 504 of the inverters 104, 106. That is, the phase wire 506a is coupled to the leg 502a of the inverter 104 and the leg 504a of the inverter 106; the phase wire 506b is coupled to the leg 502b of the inverter 104 and the leg 504b of the inverter 106; and the phase wire 506c is coupled to the leg 502c of the inverter 104 and the leg 504c of the inverter 106. As shown, the CM filter 110 is magnetically coupled to the stator windings 508. Illustratively, the CM filter core 402 is positioned at the head windings 512, and thus interacts magnetically with the head windings 512. It should be understood that in other embodiments, the CM filter core 402 may be positioned at a different location relative to the stator windings 508, for example interacting with head windings on either side of the main windings 510, interacting with windings positioned between windings 510, or other configurations.

Referring now to FIG. 6, diagram 600 illustrates simulated experimental results that may be achieved by an integrated common-mode filter core according to the system 400 shown in FIG. 4. The diagram 600 illustrates zero-sequence current (ZSC) over time for a simulated circuit including an OEW motor. In the experiment, operation of the OEW motor was simulated using Simulink with a fundamental frequency of 60 Hz and a switching frequency of 5 kHz. By using Simulink, the input voltage for the OEW motor was derived. In a further simulation, this voltage is induced to the OEW motor (RL load) both with and without the CM filter as described above. Curve 602 illustrates ZSC for a typical OEW motor without integrated filter. Curve 604 illustrates ZSC for an OEW motor with integrated common mode filter as shown in FIGS. 1-4. As shown, peak ZSC reduces from 8.3478 A (curve 602; no filter) to 1.6584 A (curve 604; with filter), an 80.13% reduction. As also shown, RMS current reduces from 3.7611 Aᵣₘₛ (no filter) to 0.9667 Aᵣₘₛ (with filter), a 74.30% reduction. Accordingly, ZSC is significantly reduced for the OEW motor with integrated common mode filter.

Although illustrated as being used with an open-end winding PMSM, the disclosed filter core reduces common-mode electromagnetic interference, and thus it should be understood that the disclosed filter design may also be used with any kind of electric machine. As described above, the integrated CM filter design disclosed herein significantly reduces zero-sequence current (3^{rd} harmonic), which may provide increased motor torque, increased output power per volume or weight, and/or otherwise improved motor efficiency.

### EXAMPLES

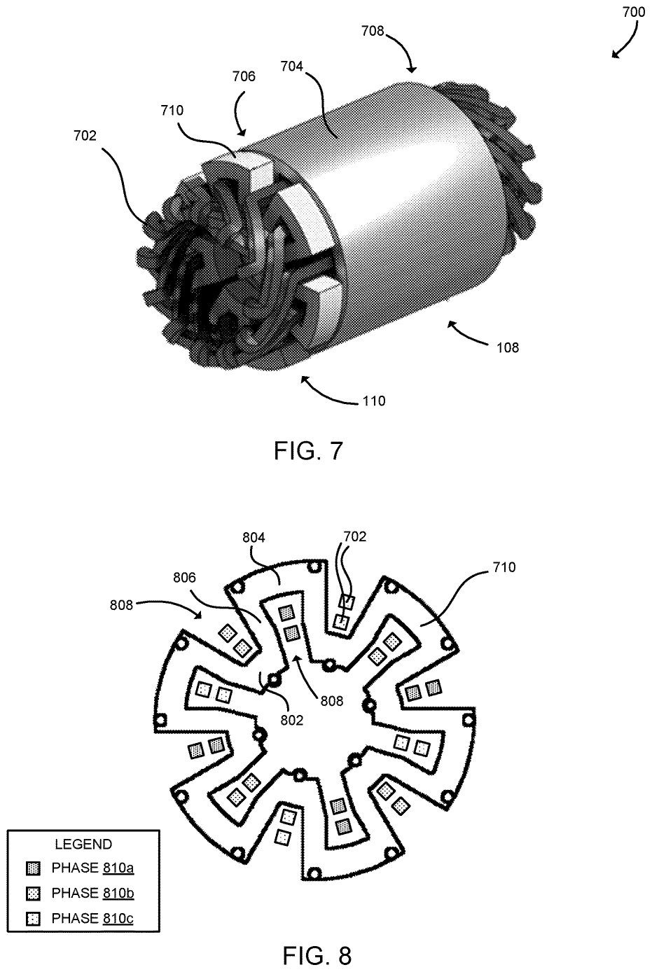

Referring now to FIGS. 7 and 8, in an experiment, an integrated common mode filter was constructed for a four-pole, twelve-slot OEW motor. FIG. 7 illustrates an integrated motor-filter system 700 according to the experiment in a perspective view. As shown, the illustrative system 700 includes multiple stator windings 702, which are arranged radially around an opening which receives a rotor (not shown). The stator windings 702 are illustratively distributed windings. The system further includes a stator core 704, which extends from one end 706 to another end 708. Twelve slots are defined through the stator core 704, each of which receives a stator winding 702 of the stator windings 702. The system 700 further includes an integrated common-mode filter core 710 positioned next to the end 706 of the stator core 704. Similar to the stator core 704, twelve slots are defined through the filter core 710, and each of those slots also receives a stator winding 702. Thus, the illustrative system 700 operates as an integrated OEW motor 108 with filter 110 as shown in FIG. 1.

FIG. 8 illustrates one potential embodiment of the filter core 710. As shown, and similar to the filter core 402 shown in FIG. 4, the filter core 710 includes six arcuate inner core segments 802 surrounding a central opening, six arcuate outer core segments 804 surrounding the inner core segments 802, and twelve radial arms 806 that extend outwardly from the inner core segments 802 to the outer core segments 804. The inner core segments 802 and the outer core segments 804 are offset such that each inner core segment 802 is connected by the radial arms 806 to two adjacent outer core segments 804, and vice versa. Twelve slots 808 are defined between the radial arm segments 806, and each slot 808 receives a stator winding 702. As shown by the legend of FIG. 8, the stator windings 702 are grouped into three phases 810a, 810b, 810c.

In an experiment, an integrated motor-filter system 700 similar to that illustrated in FIGS. 7 and 8 was operated at multiple different frequencies. As a control, the motor was also without the filter at the same frequencies. Zero-sequence current (ZSC) and total harmonic distortion (THD) were measured at each operating frequency for the integrated motor-filter system and for the control motor. Table 1, below, illustrates experimental results that were achieved for zero-sequence current (ZSC). ZSC amplitude is shown as scaled to the amplitude measured for the control motor with no filter. As shown, the integrated filter significantly reduced ZSC amplitude, and this reduction increased at higher frequencies. Table 2, below, illustrates experimental results that were achieved for phase current total harmonic distortion (THD). As shown, the integrated filter reduces THD at all frequencies, and the difference in THD between the non-filtered motor and the motor with integrated filter increased for higher frequencies.

TABLE 1
Experimental results for ZSC.

| Frequency | ZSC Amplitude | ZSC Amplitude |
|---|---|---|
| (RPM) | (no filter) | (filter) |
| 1000 RPM | 100% | 53.67% |
| 1500 RPM | 100% | 38.15% |
| 2000 RPM | 100% | 27.91% |
| 2500 RPM | 100% | 22.61% |
| 3000 RPM | 100% | 18.33% |

TABLE 2
Experimental results for THD.

| Frequency | Phase current THD | Phase current THD |
|---|---|---|
| (RPM) | (no filter) | (filter) |
| 1000 RPM | 8.71% | 7.39% |
| 1500 RPM | 8.82% | 5.76% |
| 2000 RPM | 9.50% | 4.88% |
| 2500 RPM | 10.45% | 4.35% |
| 3000 RPM | 11.47% | 3.96% |

1. A device comprising:
an electric machine comprising a stator core coupled to a plurality of stator windings, wherein the stator core comprises an elongated body extending from a first end to a second end, and wherein the stator windings have an open-end winding configuration; and
a common-mode filter core coupled to the first end of the stator core, wherein the plurality of stator windings extend through the common-mode filter core.

2. The device of claim 1, further comprising a second common-mode filter core coupled to the second end of the stator core, wherein the plurality of stator windings extend through the second common-mode filter core.

3. The device of claim 1, wherein:
the electric machine further comprises a second stator core coupled to the plurality of stator windings; and
the common-mode filter core is coupled between the stator core and the second stator core.

4. The device of claim 1, wherein the common-mode filter core comprises:
an arcuate inner core segment;
an arcuate outer core segment; and
a pair of radial arms that extend between the inner core segment and the outer core segment, wherein a slot is defined between each radial arm of the pair of radial arms, and wherein a stator winding of the plurality of stator windings is received in the slot.

5. The device of claim 1, wherein the common-mode filter core comprises:
a plurality of arcuate inner core segments distributed circumferentially around a central opening of the common-mode filter core;
a plurality of arcuate outer core segments distributed circumferentially around the plurality of inner core segments; and
a plurality of pairs of radial arms, wherein each pair of radial arms extends between an inner core segment of the plurality of inner core segments and an outer core segment of the plurality of outer core segments, wherein a slot is defined between each arm of each pair of radial arms and between each pair of radial arms, wherein a stator winding of the plurality of stator windings is received in each slot.

6. The device of claim 5, wherein:
the plurality of arcuate inner core segments comprises a first inner core segment;
the plurality of arcuate outer core segments comprises a first outer core segment and a second outer core segment; and
the plurality of pairs of radial arms comprises a first pair of radial arms and a second pair of radial arms;
wherein the first pair of radial arms couples the first inner core segment and the first outer core segment, and the second pair of radial arms couples the first inner core segment and the second outer core segment.

7. The device of claim 6, wherein a first slot is defined between the radial arms of the first pair of radial arms, a second slot is defined between the first pair of radial arms and the second pair of radial arms, and a third slot is defined between the radial arms of the second pair of radial arms, wherein the first outer core segment and the second outer core segment are separated by the third slot.

8. The device of claim 7, wherein the first slot and the second slot receive stator windings of a first phase and wherein the third slot receives stator windings of a second phase.

9. The device of claim 6, wherein:
the plurality of arcuate inner core segments further comprises a second inner core segment;
the plurality of arcuate outer core segments further comprises a third outer core segment; and
the plurality of pairs of radial arms comprises a third pair of radial arms and a fourth pair of radial arms;
wherein the third pair of radial arms couples the second inner core segment and the second outer core segment, and the fourth pair of radial arms couples the second inner core segment and the third outer core segment.

10. The device of claim 9, wherein a first slot is defined between the second pair of radial arms and the third pair of radial arms, wherein the first inner core segment and the second inner core segment are separated by the first slot.

11. The device of claim 5, wherein:
the plurality of arcuate inner core segments comprises six inner core segments;
the plurality of arcuate outer core segments comprises six outer core segments; and
the plurality of pairs of radial arms comprises twelve pairs of radial arms.

12. The device of claim 11, wherein twenty-four slots are defined between the pairs of radial arms and between each radial arm of each pair of radial arms.

13. The device of claim 5, wherein:
the plurality of arcuate inner core segments comprises twelve inner core segments;
the plurality of arcuate outer core segments comprises twelve outer core segments; and
the plurality of pairs of radial arms comprises twenty-four pairs of radial arms.

14. The device of claim 13, wherein forty-eight slots are defined between the pairs of radial arms and between each radial arm of each pair of radial arms.

15. The device of claim 1, wherein the common-mode filter core comprises:
a plurality of arcuate inner core segments distributed circumferentially around a central opening of the common-mode filter core;
a plurality of arcuate outer core segments distributed circumferentially around the plurality of inner core segments; and
a plurality of radial arms, wherein each radial arm extends between an inner core segment of the plurality of inner core segments and an outer core segment of the plurality of outer core segments, wherein a slot is defined between each of the plurality of radial arms, and wherein a stator winding of the plurality of stator windings is received in each slot.

16. The device of claim 15, wherein:
the plurality of arcuate inner core segments comprises six inner core segments;
the plurality of arcuate outer core segments comprises six outer core segments; and
the plurality of radial arms comprises twelve radial arms, wherein twelve slots are defined between the plurality of radial arms.

17. The device of claim 1, wherein the common-mode filter core comprises a soft magnetic material.

18. A device comprising:
a common-mode filter core comprising a soft magnetic material, the common-mode filter core comprising:
a plurality of arcuate inner core segments distributed circumferentially around a central opening of the common-mode filter core;
a plurality of arcuate outer core segments distributed circumferentially around the plurality of inner core segments; and
a plurality of radial arms, wherein each radial arm extends between an inner core segment of the plurality of inner core segments and an outer core segment of the plurality of outer core segments, wherein a slot is defined between each of the plurality of radial arms, and wherein each slot is configured to receive a stator winding of an electric machine.

19. The device of claim 18, wherein:
the plurality of arcuate inner core segments comprises six inner core segments;
the plurality of arcuate outer core segments comprises six outer core segments; and
the plurality of radial arms comprises twenty-four radial arms, wherein twenty-four slots are defined between the radial arms.

20. The device of claim 18, wherein:
the plurality of arcuate inner core segments comprises twelve inner core segments;
the plurality of arcuate outer core segments comprises twelve outer core segments; and
the plurality of radial arms comprises forty-eight radial arms, wherein forty-eight slots are defined between the radial arms.
